(19) United States
(12) Patent Application Publication
(10) Pub. No.: US 2026/0371724 A1
(43) Pub. Date: Nov. 19, 2026

(54) CHANNEL ISOLATION STRUCTURES IN STACKING TRANSISTORS

(71) Applicant: Taiwan Semiconductor Manufacturing Co., Ltd, Hsinchu (TW)

(72) Inventors: Zhi-Chang Lin, Zhubei City (TW); Tsung-Kai Chiu, Hsinchu (TW); Yu-Hsien Chiang, Hsinchu (TW); Chien-Lin Yu, Hsinchu (TW); Ku-Feng Yang, Baoshan Township (TW); Szuya Liao, Zhubei (TW)

(21) Appl. No.: 19/749,762

(22) Filed: Jul. 22, 2026

Related U.S. Application Data
(63) Continuation of application No. 19/009,025, filed on Jan. 3, 2025.
(60) Provisional application No. 63/700,005, filed on Sep. 27, 2024.

(51) Int. Cl. H10D 84/85; H10D 84/01

(52) U.S. Cl. CPC H10D 84/856; H10D 84/0167; H10D 84/017; H10D 84/0188; H10D 84/851

(57) ABSTRACT

Channel isolation structures and methods of forming thereof are provided. A device comprising a multi-layer stack comprising a first plurality of nanostructures; a second plurality of nanostructures over the first plurality of nanostructures; and a first channel isolation structure. The device further includes first source/drain regions on opposing ends of the first plurality of nanostructures; second source/drain regions over the first source/drain regions, the second source/drain regions being on opposing ends of the second plurality of nanostructures; a first gate structure around the first plurality of nanostructures; and a second gate structure around the second plurality of nanostructures. The first gate structure contacts a first lateral surface of the first channel isolation structure.

### PRIORITY CLAIM AND CROSS-REFERENCE

This application is a continuation of U.S. Application No. 19/700,005, filed on Sep. 27, 2024, which claims the benefit of the following provisionally filed U.S. Application No. 63/700,005, filed on Sep. 27, 2024, which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor in accordance with some embodiments.

FIGS. 2-8 are views of intermediate stages in the manufacturing of stacking transistors in accordance with some embodiments.

FIGS. 9-15 are views of intermediate stages in the manufacturing of stacking transistors in accordance with some embodiments.

FIGS. 16-18 are views of intermediate stages in the manufacturing of stacking transistors in accordance with some embodiments.

FIGS. 19-21 are views of intermediate stages in the manufacturing of stacking transistors in accordance with some embodiments.

FIGS. 22-24 are views of intermediate stages in the manufacturing of stacking transistors in accordance with some embodiments.

FIGS. 25, 26, 27A, 27B, 27C, 28, 29A, 29B and 29C, are views of intermediate stages in the manufacturing of stacking transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor structure including an upper transistor and a lower transistor that are vertically stacked and the method of forming the same are provided. Channel isolation structures are formed between and isolate upper channel regions of the upper transistor from lower channel regions of the lower transistor. The channel isolation structures may be formed separately from other isolation structures in the device, such as inner spacers that separate the upper and lower gate stacks from directly contacting upper and lower source/drain regions. Embodiment channel isolation structures provide improved electrical performance (e.g., improved alternating current (AC) flow, improved leakage, or the like) formed by simplified processes flows that are readily implementable.

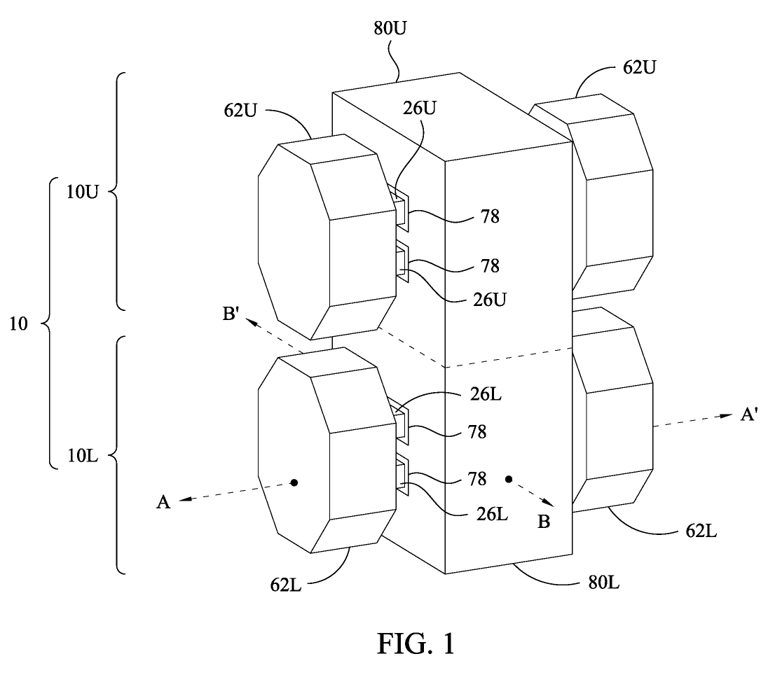

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A' is a vertical cross-section that is parallel to a longitudinal axis of the semiconductor nanostructures 26 of a stacking transistor and in a direction of, for example, a current flow between the source/drain regions 62 of the stacking transistor. Subsequent figures illustrate details along the cross-section A-A'.

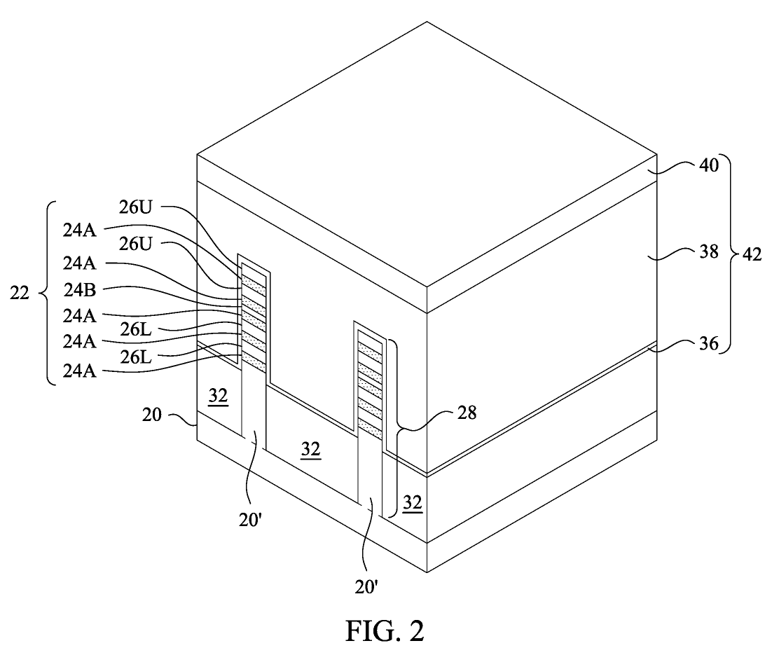

FIGS. 2-8 illustrate perspective and the cross-sectional views of intermediate stages in the formation of stacking transistors (as schematically represented in FIG. 1) in accordance with some embodiments. In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20’ (patterned portions of the semiconductor substrate 20, also referred to as semiconductor fins 20') and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and the dummy nanostructures 24B may be formed of germanium or silicon germanium with a higher germanium atomic percentage than the dummy nanostructures 24A. For example, the dummy nanostructures 24A may be made of silicon germanium with a germanium concentration of about 5% to 30% or about 15% to 30%, and the dummy nanostructures 24B may be made of silicon germanium with a germanium concentration of about 30% to 60% or about 35% to about 60%. It has been observed that by modulating the germanium concentration of the dummy nanostructures 24A/24B to be in the above ranges, sufficient etch selectively can be achieved, allowing the dummy nanostructures 24B can be selectively removed in subsequent processes with substantially removing the dummy nanostructures 24A. For example, it has been observed that when the germanium concentration of the dummy nanostructures 24A is less than 15%, the dummy nanostructures 24A may not be fully removed during the replacement gate process. Further, it has been observed that when the germanium concentration of the dummy nanostructures 24A is greater than 30% and the germanium concentration of the dummy nanostructures 24B is less than 35%, the etch selectivity between the dummy nanostructures 24A and 24B may not be sufficiently high. As a result, the dummy nanostructures 24B can not be fully removed while leaving at least a portion of the dummy nanostructures 24A intact during subsequent processing.

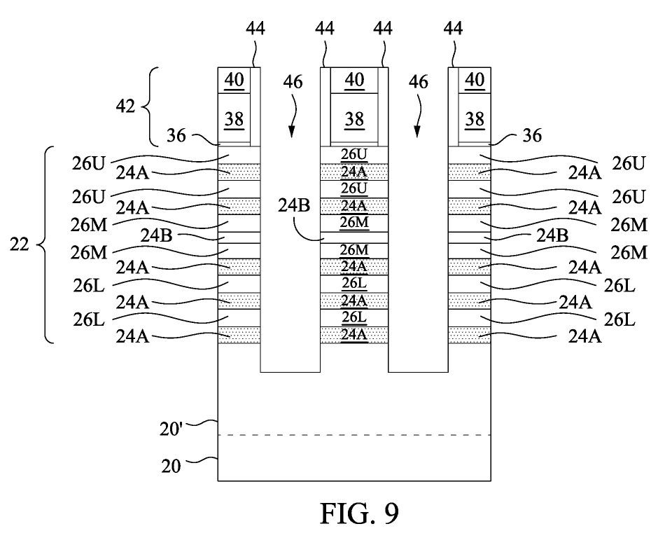

The lower semiconductor nanostructures 26L will provide channel regions for lower nanostructure-FETs of the CFETs. The upper semiconductor nanostructures 26U will provide channel regions for upper nanostructure-FETs of the CFETs. The dummy nanostructures 24B may be formed in direct contact with two dummy nanostructures 24A and may not contact any semiconductor nanostructures 26. Compared to subsequently described embodiments (e.g., see FIGS. 9-29C), semiconductor nanostructures 26 that are immediately above/below (e.g., in contact with) the dummy nanostructures 24B are excluded, and all semiconductor nanostructures 26 may provide channel regions in the resulting device. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20', the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

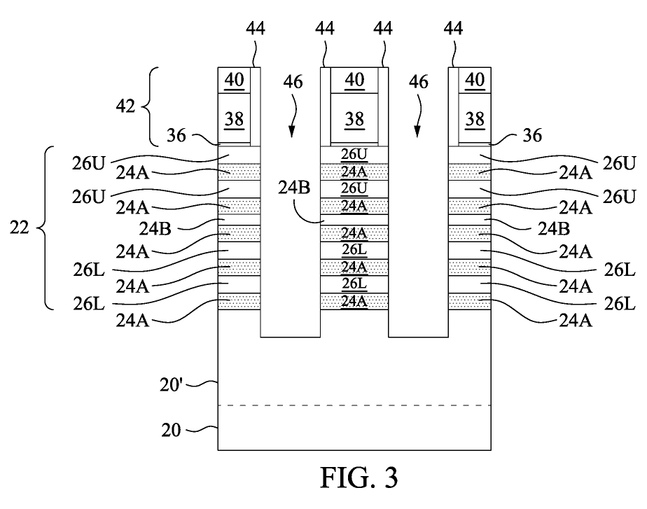

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20’. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

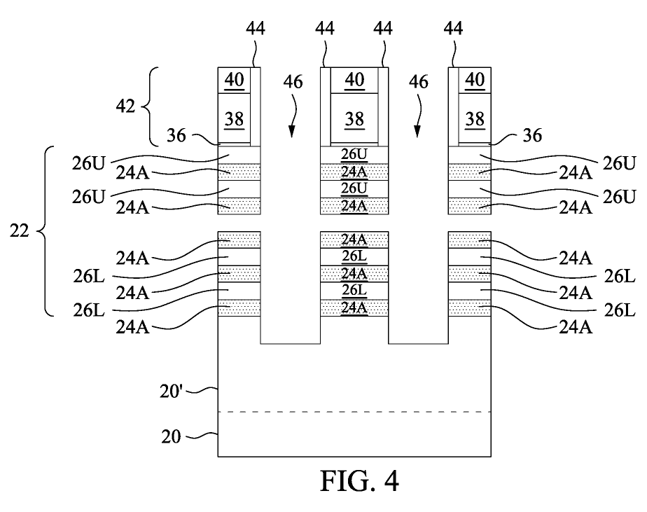

In FIGS. 4-6, inner spacers 54 and channel isolation structures 56 are formed in separate steps, which allow for increased control while forming the inner spacers 54 and the channel isolation structures 56. For example, materials, thicknesses, or the like of the inner spacers 54 and the channel isolation structures 56 can be independently selected and controlled, resulting in improved electrical performance (e.g., improved AC flow, reduced leakage, or the like) while still providing a feasible process flow that can be readily implemented. Further, by independently forming the channel isolation structures 56, the dummy nanostructures 24A can be formed directly between and contacting the dummy nanostructures 24B without any intervening semiconductor nanostructures 26. As a result, dummy semiconductor nanostructures (e.g., dummy semiconductor nanostructures 26M, see FIGS. 9-29C) can be advantageously omitted from the manufacturing process and the resulting structure, which future reduces leakage in the resulting device. By omitting such dummy semiconductor nanostructures (e.g., dummy semiconductor nanostructures 26M, see FIGS. 9-29C), leakage current through the dummy semiconductor nanostructures can also be avoided.

In FIG. 4, forming the channel isolation structures 56 may include an etching process that removes the dummy nanostructure 24B. The etching process may be isotropic and may be selective to the material of the dummy nanostructures 24B, so that the dummy nanostructures 24B are etched at a faster rate than the semiconductor nanostructures 26 and the dummy nanostructures 24A. In this manner, the dummy nanostructures 24B may be completely removed from between the lower semiconductor nanostructures 26L (collectively) and the upper semiconductor nanostructures 26U (collectively) without removing the semiconductor nanostructures 26 or the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Alternatively, the etch process may be a wet etch process with an etchant having an etch selectivity between the dummy nanostructures 24A and the dummy nanostructures 24B that is greater than 40 (e.g., in a range from 40 to 100). The wet etch process may include dispensing a liquid etchant over the device or immersing the device in a liquid etchant. The liquid etchant may include one or more elements/compounds (e.g., H₂O₂, O₃, or the like) that oxidize germanium (e.g., the germanium in the dummy nanostructures 24A and 24B) and include one or more elements/compounds that etch away the oxidized germanium. Because the dummy nanostructures 24B have a sufficiently higher germanium concentration (e.g., in the ranges described above) than the dummy nanostructures 24A, etch selectivity can be achieved. Further, because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B.

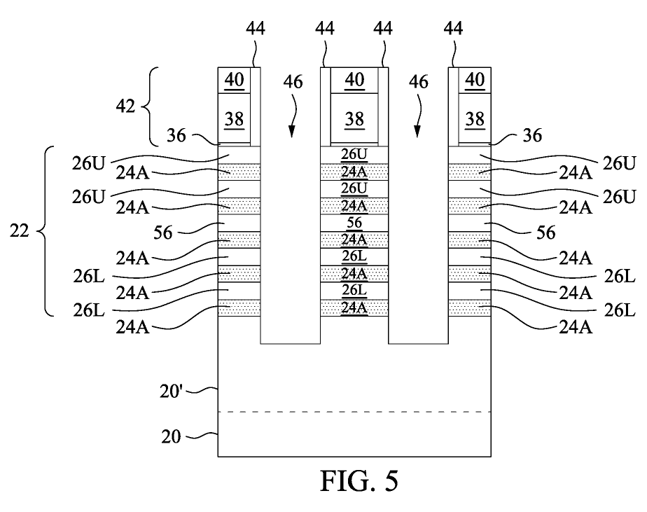

In FIG. 5, channel isolation structures 56 are formed between the upper semiconductor nanostructures 26U (collectively) and the lower semiconductor nanostructures 26L (collectively). As subsequently described in greater detail, source/drain regions will be subsequently formed in the source/drain recesses 46. Channel isolation structures bmay be used to isolate the upper semiconductor nanostructures 26U (collectively) from the lower semiconductor nanostructures 26L (collectively). The channel isolation structures bmay be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.9 may be utilized. The insulating material may be formed by a deposition process, such as ALD, CVD, or the like. The etching of the insulating material may be anisotropic or isotropic. The insulating material, when etched, has portions remaining in between the upper and lower semiconductor nanostructures 26U and 26L, thus forming the channel isolation structures 56.

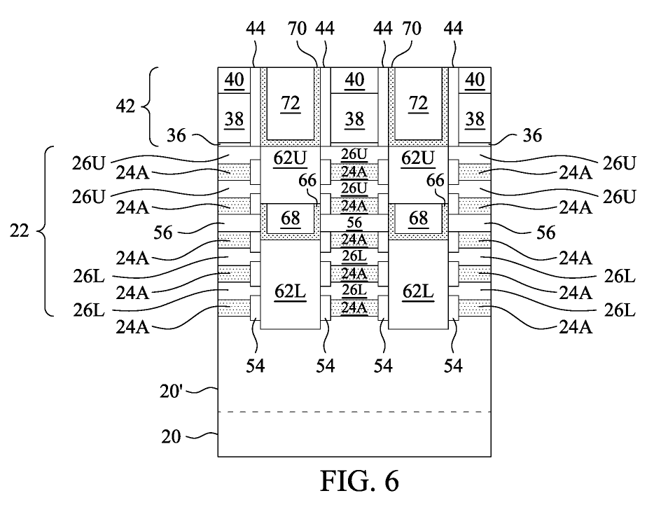

Subsequently, in FIG. 6, inner spacers 54 are formed on sidewalls of the dummy nanostructures 24A. Forming the inner spacers 54 may include an etching process that recesses sidewalls of the dummy nanostructures 24A away from sidewalls of the semiconductor nanostructures 26 and the channel isolation structures 56. The etching process may be isotropic and may be selective to the material of the dummy nanostructures 24A, so that the dummy nanostructures 24A are etched at a faster rate than the semiconductor nanostructures 26 and the channel isolation structures 56. In this manner, the dummy nanostructures 24A may be recessed without removing the semiconductor nanostructures 26 or the channel isolation structures 56. In some embodiments, recessing the dummy nanostructures 24A may partially etch exposed surfaces of the semiconductor nanostructures 26, including top and/or bottom surfaces of the semiconductor nanostructures 26, in outer regions of the semiconductor nanostructures 26. The etch process may comprise a dry etch process using chlorine gas, with or without a plasma. Although sidewalls of the dummy nanostructures 24A are illustrated as being straight after the etching, the sidewalls may be concave or convex.

Inner spacers 54 are then formed on the recessed sidewalls of the dummy nanostructures 24A. As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. The inner spacers 54 may be formed by conformally depositing an insulating material in the source/drain recesses 46, on sidewalls of the dummy nanostructures 24A, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.9 may be utilized. The insulating material may be formed by a deposition process, such as ALD, CVD, or the like. The etching of the insulating material may be anisotropic or isotropic. The insulating material, when etched, has portions remaining on the sidewalls of the dummy nanostructures 24A, thus forming the inner spacers 54. The material composition of the channel isolation structures 56 may be the same or different than the material composition of the inner spacers 54.

As also illustrated by FIG. 6, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper epitaxial source/drain regions 62U may remain separated after the epitaxy process or may be merged.

After the upper epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 86 (if present) or the dummy gates 84 are substantially coplanar (within process variations). Accordingly, the top surfaces of the masks 40 (if present) or the dummy gates 38 are exposed through the second ILD 72. In the illustrated embodiment, the masks 40 remain after the removal process. In other embodiments, the masks 40 are removed such that the top surfaces of the dummy gates 38 are exposed through the second ILD 72.

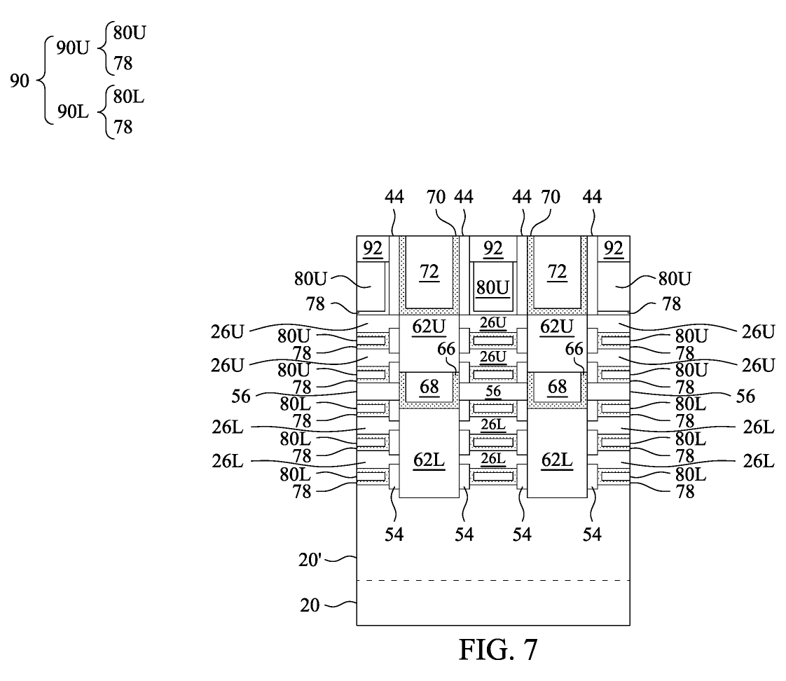

FIG. 7 illustrates a replacement gate process to replace the dummy gate stacks 42 and the dummy nanostructures 24A with gate stacks 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the channel isolation structures 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20'; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20'. Further, the lower gate structures 90L and the upper gate structures 90U may each be in direct physical contact with the channel isolation structures 56 due to the omission of any intervening dummy semiconductor nanostructures on the channel isolation structures 56.

As also shown in FIG. 7, gate masks 92 are formed over the gate stacks 42. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

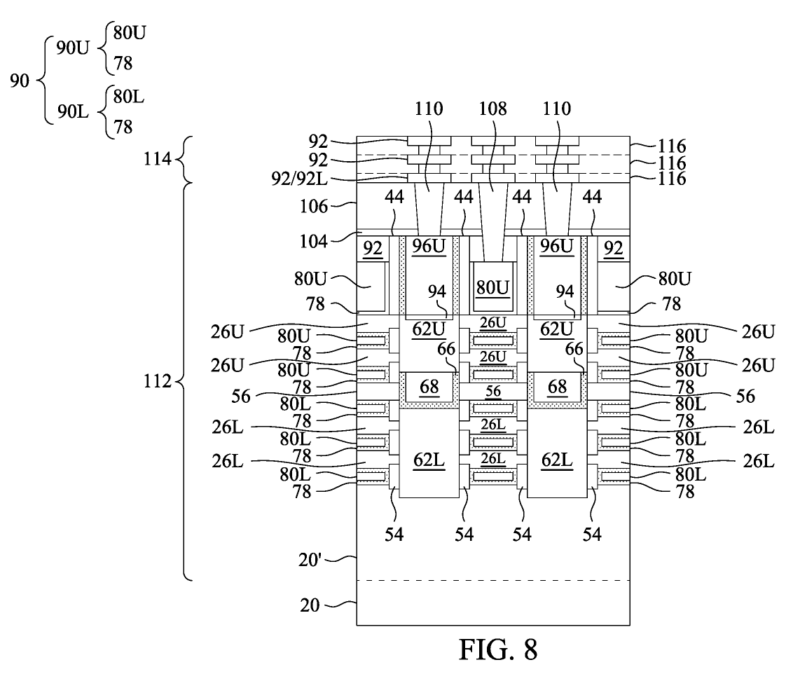

In FIG. 8, metal-semiconductor alloy regions 94 and source/drain contacts 96 are formed through the second ILD 72 to electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate stacks 90L and the lower gate electrode 80L may be made through a backside of the device layer 112 (e.g., a side opposite to the front-side interconnect structure 114).

FIGS. 9-14 illustrate cross-sectional views of intermediate process steps of forming a stacking transistor according to some other embodiments where the channel isolation structures 56 have a multilayer structure. In FIGS. 9 -14, like reference numerals indicate like elements formed by like processes as discussed above with respect to FIGS. 2- 8 unless otherwise noted. FIG. 9 illustrates a structure at a similar stage of processing as FIG. 3 described above, where the source/drain recesses 46 are patterned through the multi-layer stack 22. However, in FIG. 9, the dummy nanostructures 24B are not formed directly between dummy nanostructures 24A. Instead, dummy semiconductor nanostructures 26M are disposed on top and bottom surfaces of the dummy nanostructures 24B. The dummy semiconductor nanostructures 26M may be formed a same material and using the same processes as the upper semiconductor nanostructures 26U and the lower semiconductor nanostructures 26L. For example, in some embodiments, the upper semiconductor nanostructures 26U, the lower semiconductor nanostructures 26L, and the dummy semiconductor nanostructures 26M may be formed of silicon while the dummy nanostructures 24A and the dummy nanostructures 24B are formed of silicon germanium with different germanium concentrations. The dummy semiconductor nanostructures 26M may also be referred to as middle semiconductor nanostructures and may help define a boundary between the upper and lower transistors in the stacking transistor. The dummy semiconductor nanostructures 26M may be used to widen a process window for forming channel isolation structures such that the etch selectivity window between the dummy nanostructures 24A and 24B can be relaxed because the etch selectivity between the dummy nanostructures 24B (e.g., high germanium concentration silicon germanium) is generally greater compared to the dummy semiconductor nanostructures 26M (e.g., silicon) than the dummy nanostructures 24A (e.g., low germanium concentration silicon germanium).

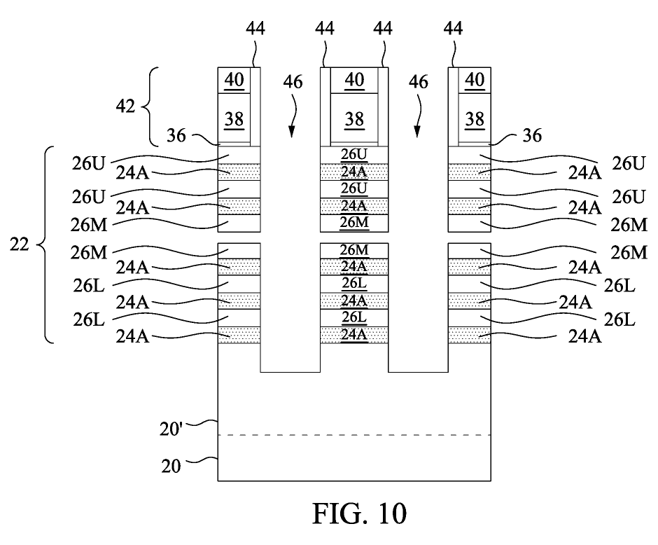

In FIGS. 10, the dummy nanostructures 24B are removed. Removing the dummy nanostructures 24B may include an etching process similar to the process described above with respect to FIG. 4. For example, the etching process may be isotropic and may be selective to the material of the dummy nanostructures 24B, so that the dummy nanostructures 24B are etched at a faster rate than the upper semiconductor nanostructures 26U, the dummy semiconductor nanostructures 26M, the lower semiconductor nanostructures 26L, and the dummy nanostructures 24A. In this manner, the dummy nanostructures 24B may be completely removed from between the lower semiconductor nanostructures 26L (collectively) and the upper semiconductor nanostructures 26U (collectively) without removing the semiconductor nanostructures 26, the dummy semiconductor nanostructures 26M, or the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 and dummy semiconductor nanostructures 26M are formed of silicon free from germanium, the etch process may comprise a dry etch process using chlorine gas, with or without a plasma. Alternatively, the etch process may be a wet etch process with an etchant having an etch selectivity between the dummy nanostructures 24A and the dummy nanostructures 24B that is greater than 40 (e.g., in a range from 40 to 100). The wet etch process may include dispensing a liquid etchant over the device or immersing the device in a liquid etchant. The liquid etchant may include one or more one or more elements/compounds (e.g., H₂O₂, O₃, or the like) that oxidize germanium (e.g., the germanium in the dummy nanostructures 24A and 24B) and include one or more elements/compounds that etch away the oxidized germanium. Because the dummy nanostructures 24B have a sufficiently higher germanium concentration (e.g., in the ranges described above) than the dummy nanostructures 24A, etch selectivity can be achieved. Further, because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B.

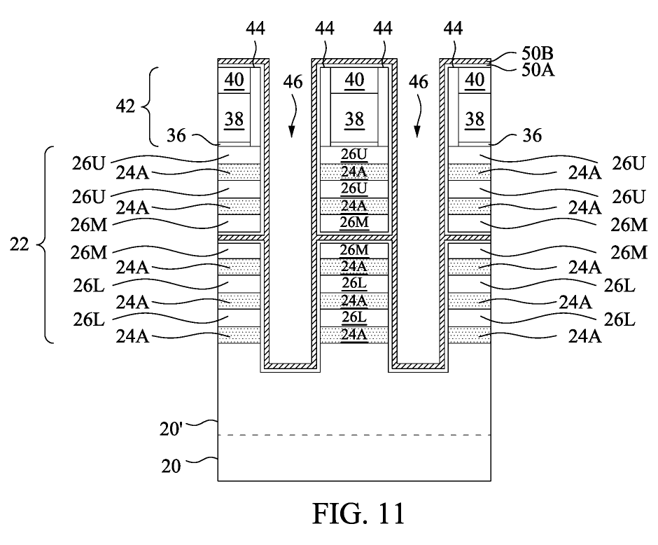

In FIG. 11, dielectric material layers 50A and 50B are sequentially deposited in the source/drain recesses 46, on sidewalls of the dummy nanostructures 24A, on sidewalls of the semiconductor nanostructures 26, on sidewalls of the dummy semiconductor nanostructures 26M, and between the upper and lower semiconductor nanostructures 26U and 26L using a suitable conformal deposition process, such as CVD, ALD, or the like. Specifically, the dielectric material layer 50A may be formed in contact with lateral surfaces of the dummy semiconductor nanostructures 26M, and the dielectric material layer 50B may fill remaining spaces between vertically stacked ones of the dummy semiconductor nanostructures 26M. The dielectric material layers 50A and 50B may have different material compositions. For example, the dielectric material layer 50A may be a relatively hard dielectric material, such as a carbon-containing dielectric material, such as silicon oxycarbonitride, silicon oxycarbide, silicon oxynitride, or the like with a relatively high k-value. In some embodiments, the dielectric material layer 50A may be a high-k material with a k-value in a range of about 3.9 to about 10. In contrast, the dielectric material layer 50B may be made of a relatively low-k dielectric material having a k-value less than about 3.9. In some embodiments, the dielectric material layer 50B has a lower k-value than the dielectric material layer 50A while the dielectric material layer 50A is harder (e.g., has a higher etch resistance relative a same etch process) than the dielectric material layer 50B. By using a combination of materials, the resulting channel isolation structure may be relatively strong and less susceptible to damage during subsequent process steps (e.g., due to the inclusion of the hard material of the dielectric material layer 50A) while still having a low-k value for improved isolation (e.g., due to the inclusion of the low-k dielectric material layer 50B). As such, the resulting stacking transistor can have improved electrical performance (e.g., improved AC flow) and can be readily formed with a feasible manufacturing process.

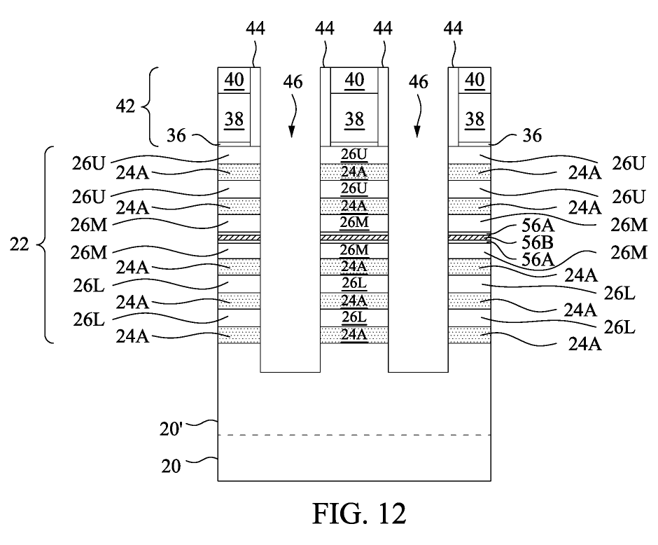

In FIG. 12, an etching process is performed to remove the dielectric material layers 50A and 50B from sidewalls of the source/drain recesses 46, the sidewalls of the gate spacers 44, and from over the dummy gate stacks 42. Remaining portions of the dielectric material layers 50A and 50B form channel isolation material 56A and channel isolation material 56B, respectively. The channel isolation material 56B may be disposed between upper and lower portions of the channel isolation material 56A. As subsequently described in greater detail, source/drain regions will be subsequently formed in the source/drain recesses 46. The channel isolation material 56A and the channel isolation material 56B may be used to isolate the upper semiconductor nanostructures 26U (collectively) from the lower semiconductor nanostructures 26L (collectively). The etching of the dielectric material layers 50A and 50B may be anisotropic or isotropic.

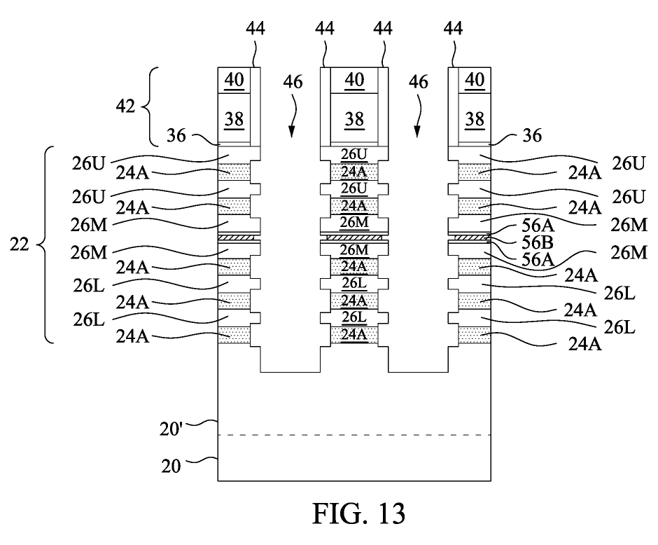

In FIG. 13, an etching process is performed that recesses sidewalls of the dummy nanostructures 24A away from sidewalls of the semiconductor nanostructures 26 and the channel isolation materials 56A and 56B. The etching process may be isotropic and may be selective to the material of the dummy nanostructures 24A, so that the dummy nanostructures 24A are etched at a faster rate than the semiconductor nanostructures 26 and the channel isolation materials 56A and 56B. In this manner, the dummy nanostructures 24A may be recessed without removing the semiconductor nanostructures 26 or the channel isolation structures 56. In some embodiments, recessing the dummy nanostructures 24A may partially etch exposed surfaces of the semiconductor nanostructures 26, including top and/or bottom surfaces of the semiconductor nanostructures 26, in outer regions of the semiconductor nanostructures 26. The etch process may also partially recess sidewalls of the channel isolation material 56B (and optionally, to a lesser degree, the channel isolation material 56A). However, due to the relative hardness of the channel isolation material 56A, the channel isolation material 56A remains relatively unetched and the overall channel isolation structure is kept intact even when the channel isolation material 56B is recessed. The etch process may comprise a dry etch process using chlorine gas, with or without a plasma. Although sidewalls of the dummy nanostructures 24A are illustrated as being straight after the etching, the sidewalls may be concave or convex.

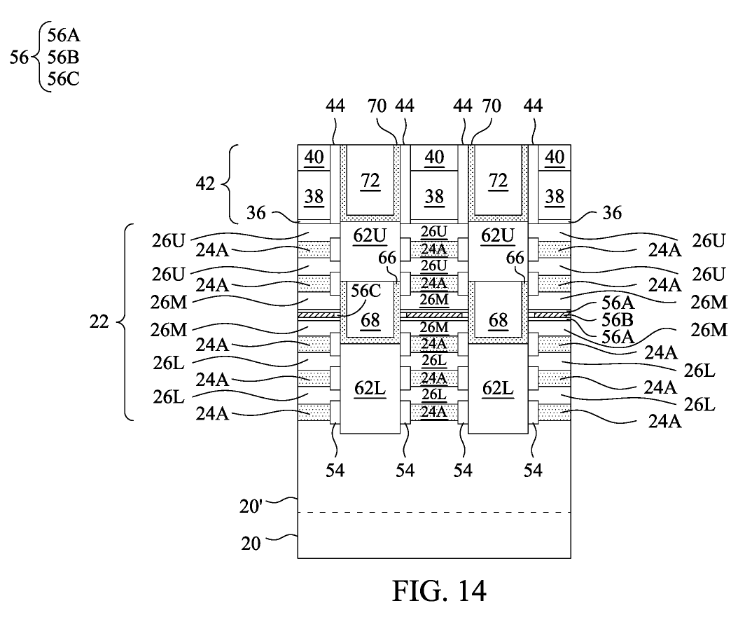

Subsequently, in FIG. 14, inner spacers 54 are then formed on the recessed sidewalls of the dummy nanostructures 24A. The inner spacers 54 may be formed of a similar material and similar processes as described above with respect to FIG. 6. For example, the inner spacers 54 may be formed by conformally depositing an insulating material in the source/drain recesses 46, on sidewalls of the dummy nanostructures 24A, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.9 may be utilized. Portions of the insulating material on recessed sidewalls of the channel isolation material 56B may be patterned to form channel isolation material 56C. The channel isolation material 56C has a same material composition and is formed in a same process as the inner spacers 54. The resulting multi-layer channel isolation structure 56 includes the relatively hard channel isolation material 56A, the low-k channel isolation material 56B sandwiched between the channel isolation material 56A, and the channel isolation material 56C on sidewalls of the channel isolation material 56B. The material composition of the channel isolation materials 56A/56B may be the same or different than the material composition of the inner spacers 54.

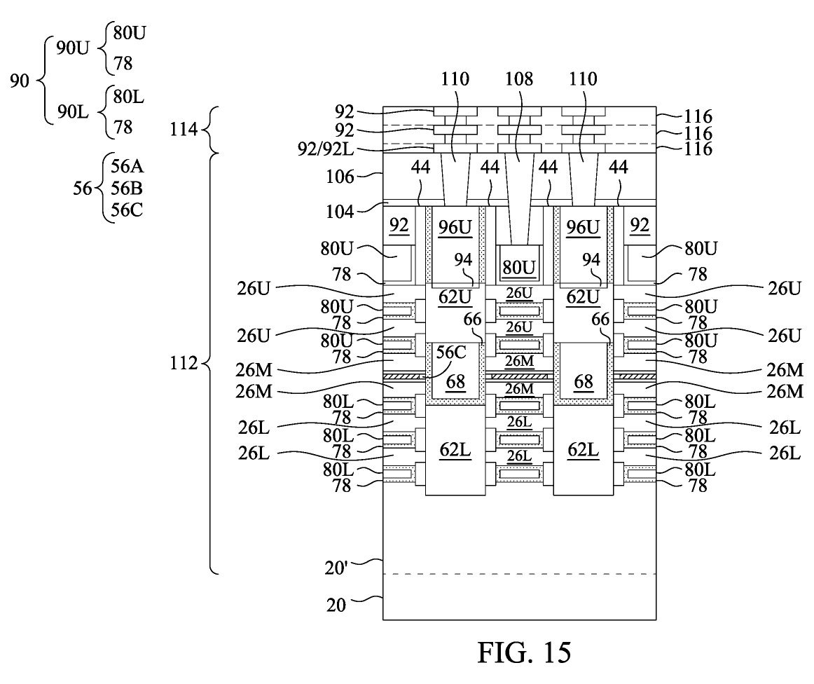

As further illustrated by FIG. 14, upper and lower epitaxial source/drain regions 62U and 62L, CESLs 66 and 70, and ILDs 68 and 72 are formed in the source/drain recesses 46. Additional processing steps, including a replacement gate process, gate and source/drain contact formation, and front-side interconnect formation as described above may be performed to arrive at the structure of FIG. 15. FIG. 15 illustrates a similar structure as FIG. 8 where like reference numerals indicate like elements. However, the channel isolation structures 56 of FIG. 15 is a multi-layer structure with the relatively hard channel isolation material 56A, the low-k channel isolation material 56B sandwiched between the channel isolation material 56A, and the channel isolation material 56C on sidewalls of the channel isolation material 56B. Further, the dummy semiconductor nanostructures 26M may remain in the resulting device, and separate the channel isolation structure 56 from the upper and lower gate structures 90U and 90L. The dummy semiconductor nanostructures 26M may not act as channel regions as they do not adjoin any epitaxial source/drain regions.

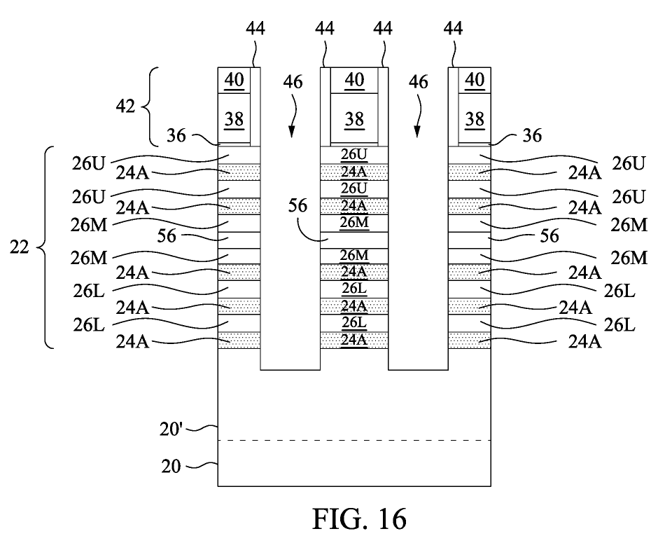

FIGS. 16-18 illustrate cross-sectional views of intermediate process steps of forming a stacking transistor according to some other embodiments where the channel isolation structures 56 have is made of a single material and dummy semiconductor nanostructures 26M are included. In FIGS. 16-18, like reference numerals indicate like elements formed by like processes as discussed above with respect to FIGS. 2-15 unless otherwise noted. FIG. 16 illustrates a structure at a similar stage of processing as FIG. 12 described above, where the source/drain recesses 46 are patterned through the multi-layer stack 22 and the channel isolation structure 56 is formed between the upper semiconductor nanostructures 26U (collectively) and the lower semiconductor nanostructures 26L (collectively). However, in FIG. 16, the channel isolation structures 56 does not have a multi-layer structure and is made of a single material. In some embodiments, the channel isolation structures 56 is made of a hard dielectric material, such as a carbon-containing dielectric material, such as silicon oxycarbonitride, silicon oxycarbide, silicon oxynitride, or the like. The channel isolation structures 56 may be formed in direct contact with dummy semiconductor nanostructures 26M.

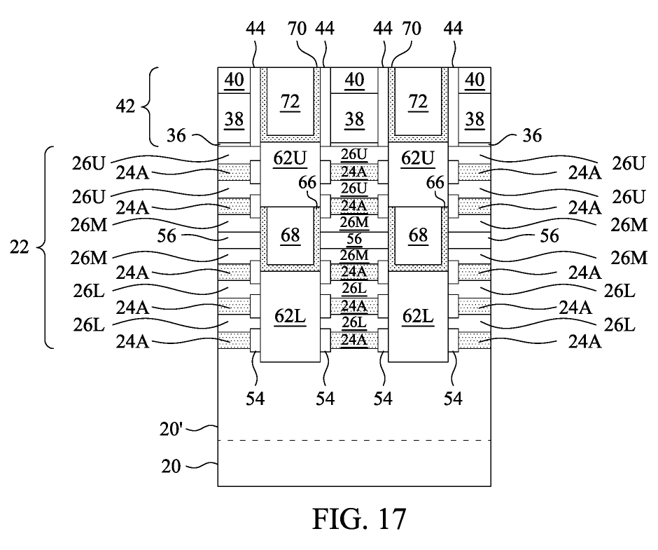

In FIG. 17, inner spacers 54 are formed on sidewalls of the dummy nanostructures 24A. The inner spacers 54 may be formed of a similar material using similar processes as those described above. Similar to the above embodiments, the inner spacers 54 and the channel isolation structures 56 may be formed in separate processes to allow for increased flexibility and control in forming different isolation structures in the stacking transistor. The inner spacers 54 may be formed a same material or a different material than the channel isolation structures 56. Further, upper and lower epitaxial source/drain regions 62U and 62L, CESLs 66 and 70, and ILDs 68 and 72 may also be formed in the source/drain recesses 46.

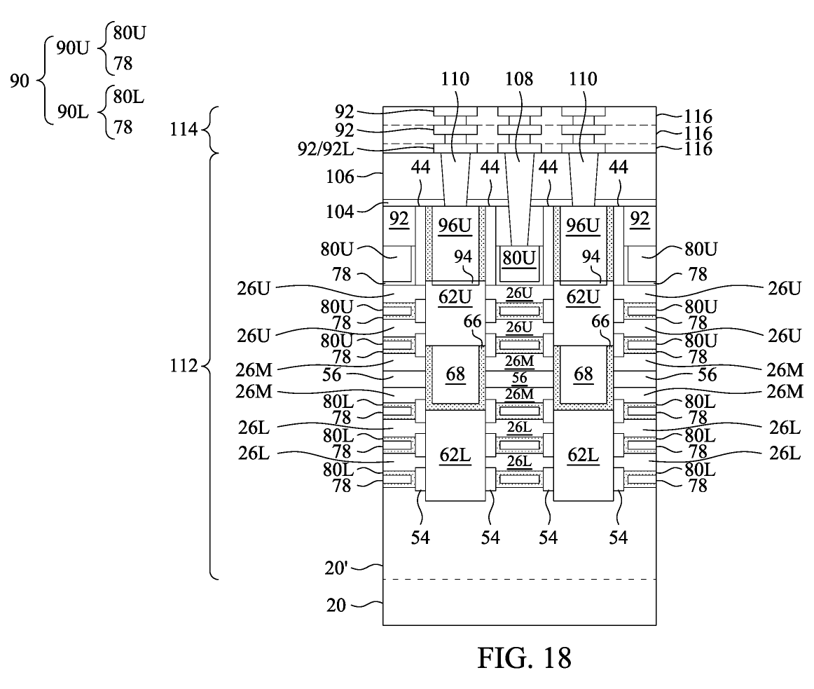

Additional processing steps, including a replacement gate process, gate and source/drain contact formation, and front-side interconnect formation as described above may be performed to arrive at the structure of FIG. 18. FIG. 18 illustrates a similar structure as FIG. 15 where like reference numerals indicate like elements. However, the channel isolation structures 56 of FIG. 18 is not a multi-layer structure and is made of a single material.

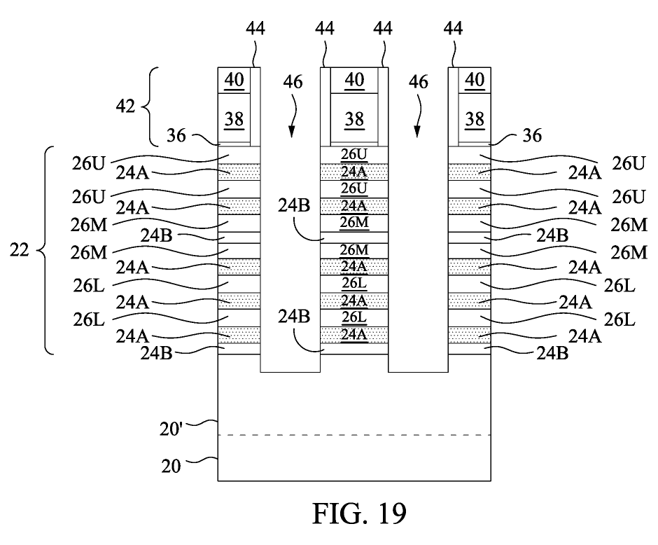

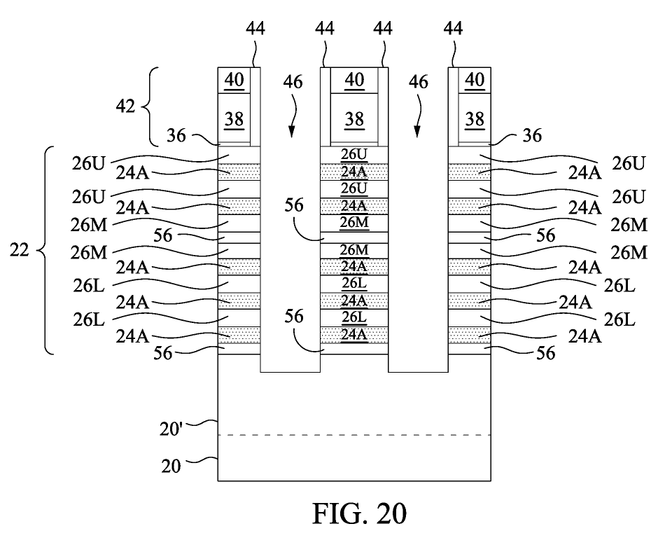

Although the channel isolation structures 56 are illustrated as only being disposed between and separating the upper semiconductor nanostructures 26U (collectively) and the lower semiconductor nanostructures 26L (collectively) in the above embodiments, the channel isolation structures 56 may also be formed in other locations relative to the semiconductor nanostructures 26. For example, FIGS. 19-21 illustrate intermediate stages of manufacturing embodiments where the channel isolation structures 56 are also formed under the lower semiconductor nanostructures 26L, such as under the lower gate stack 90L. The channel isolation structures 56 may be formed between the lower gate stack 90L and the underlying semiconductor fin 20’/substrate 20 to improve isolation in bottom regions of the stacking transistor and further reduce leakage in the resulting device. For example, the channel isolation structures 56 under the lower gate stack 90L may reduce leakage from the lower epitaxial source/drain regions 62L through the semiconductor fin 20’ and the semiconductor substrate 20. The channel isolation structures 56 may be formed in direct contact with the lower gate stack 90L and the semiconductor fin 20’. The channel isolation structures 56 may be formed of like processes and like materials as described above with the lower channel isolation structures 56 (e.g., under the lower semiconductor nanostructures 26L) being formed by first forming dummy nanostructures 24B under the lower semiconductor nanostructures 26L, see FIG. 19. For example, the dummy nanostructures 24B may be formed in direct contact with top surfaces of the semiconductor fins 20’. The dummy nanostructures 24B may then be replaced with channel isolation structures 56 as described above as illustrated in FIG. 20.

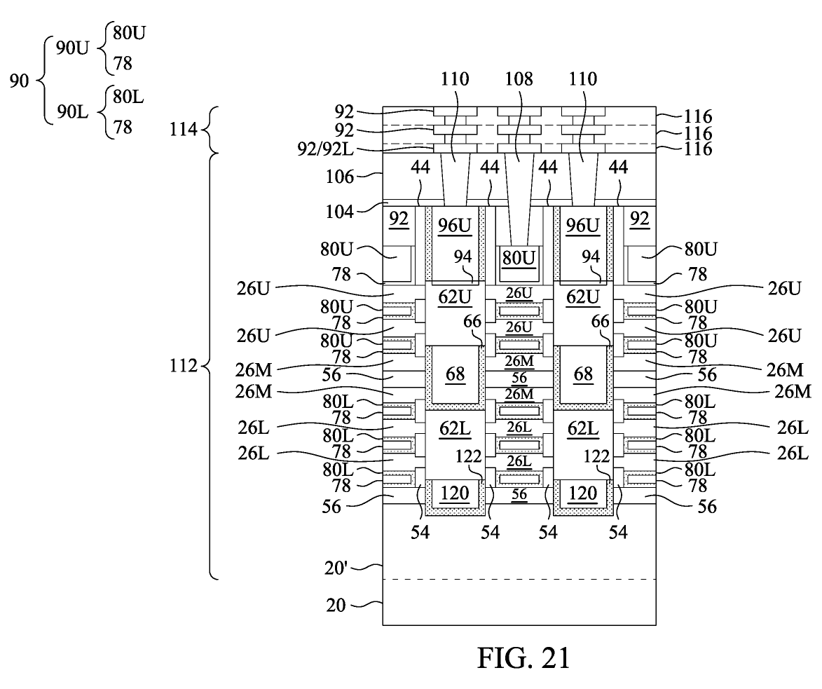

Additional processing steps, including forming inner spacers 54, forming upper and lower epitaxial source/drain regions 62L and 62U, forming CESLs 66 and 70, forming ILDs 68 and 72, a replacement gate process, gate and source/drain contact formation, and front-side interconnect formation as described above may be performed to arrive at the structure of FIG. 21. As further illustrated by FIG. 21, bottom ILD 120 and a bottom CESL 122 may be formed under the lower epitaxial source/drain regions 62L, such as between the lower epitaxial source/drain regions 62L and the semiconductor fins 20’. The bottom ILD 120 and the bottom CESL 122 may be formed in the source/drain recesses 46 prior to forming the lower epitaxial source/drain regions 62L using similar materials and similar processes as the first ILD 68 and the first CESL 66, respectively. The bottom ILD 120 and the bottom CESL 122 may further reduce leakage from the lower epitaxial source/drain regions 62L through the semiconductor fins 20’.

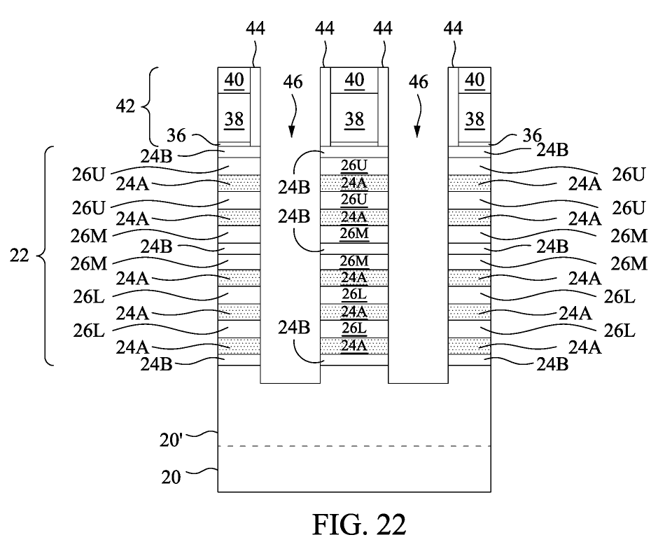

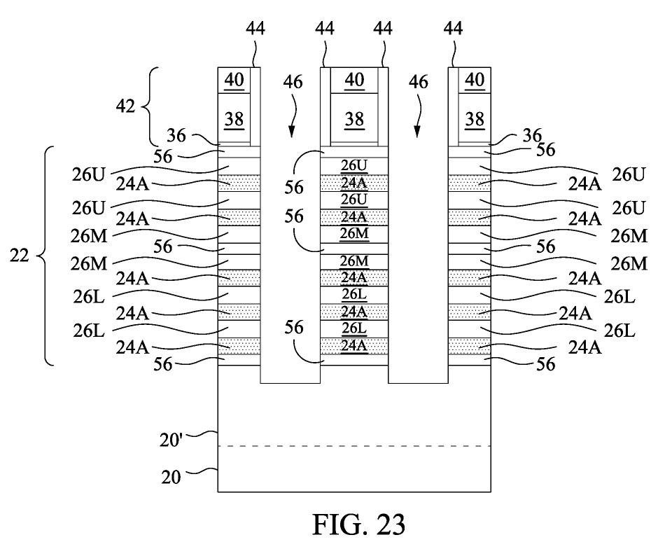

As another example, FIGS. 22-24 illustrate intermediate stages of manufacturing embodiments where the channel isolation structures 56 are formed under the lower semiconductor nanostructures 26L, such as under the lower gate stack 90L, as well as over the upper semiconductor nanostructures 26U. The channel isolation structures 56 may be formed between the lower gate stack 90L and the underlying semiconductor fin 20’/substrate 20 to improve isolation in bottom regions of the stacking transistor and further reduce leakage in the resulting device. For example, the channel isolation structures 56 under the lower gate stack 90L may reduce leakage from the lower epitaxial source/drain regions 62L through the semiconductor fin 20’ and the semiconductor substrate 20. The channel isolation structures over the upper semiconductor nanostructures 26U may be used to protect the upper semiconductor nanostructures 26U during processing for improved nanostructure profile and control. The channel isolation structures 56 may be formed of like processes and like materials as described above. As illustrated by FIG. 22, the lower channel isolation structures 56 (e.g., under the lower semiconductor nanostructures 26L) being formed by first forming dummy nanostructures 24B under the lower semiconductor nanostructures 26L, and the upper channel isolation structures 56 (e.g., over the upper semiconductor nanostructures 26U) may be formed by first forming dummy nanostructures 24B over the upper semiconductor nanostructures 26U. For example, the dummy nanostructures 24B may be formed in direct contact with top surfaces of the semiconductor fins 20’ as well as in direct contact with topmost ones of the upper semiconductor nanostructures 26U. The dummy nanostructures 24B may then be replaced with channel isolation structures 56 as described above as illustrated in FIG. 23.

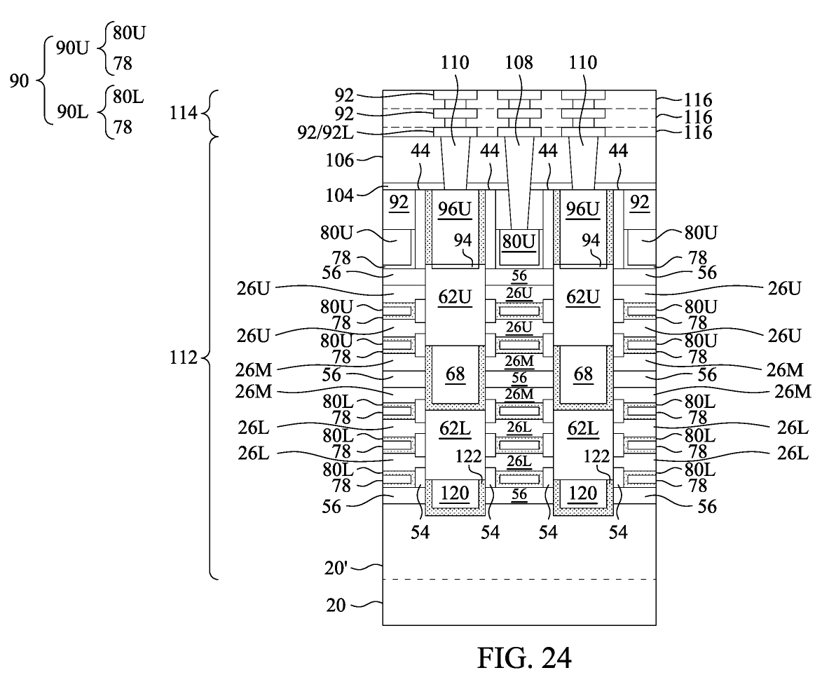

Additional processing steps, including forming inner spacers 54, forming upper and lower epitaxial source/drain regions 62L and 62U, forming CESLs 66 and 70, forming ILDs 68 and 72, a replacement gate process, gate and source/drain contact formation, and front-side interconnect formation as described above may be performed to arrive at the structure of FIG. 21. As further illustrated by FIG. 24, bottom ILD 120 and a bottom CESL 122 may be formed under the lower epitaxial source/drain regions 62L, such as between the lower epitaxial source/drain regions 62L and the semiconductor fins 20’. The bottom ILD 120 and the bottom CESL 122 may be formed in the source/drain recesses 46 prior to forming the lower epitaxial source/drain regions 62L using similar materials and similar processes as the first ILD 68 and the first CESL 66, respectively. The bottom ILD 120 and the bottom CESL 122 may further reduce leakage from the lower epitaxial source/drain regions 62L through the semiconductor fins 20’.

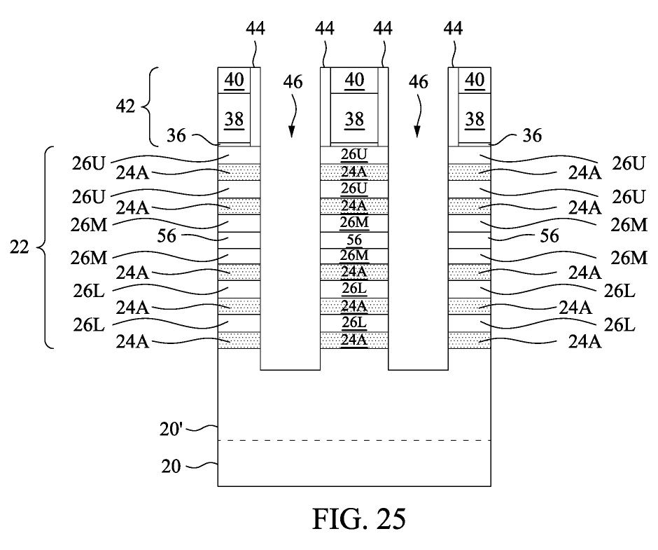

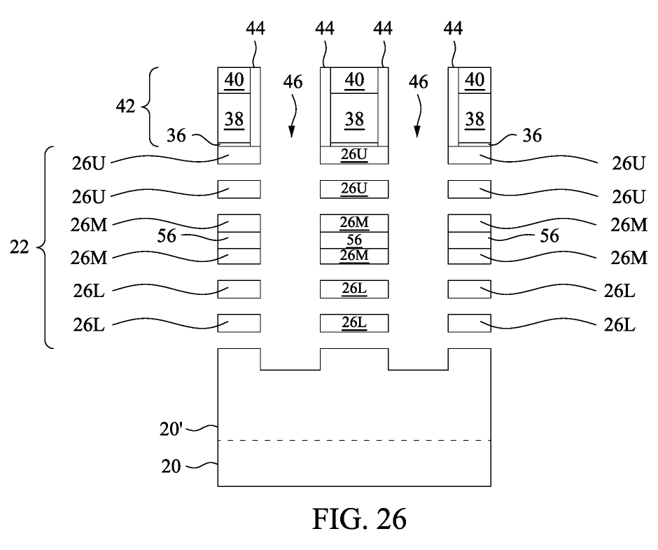

In the various embodiments described above, the dummy nanostructures 24A are removed after forming the epitaxial source/drain regions as part of the replacement gate process. In other embodiments, the dummy nanostructures 24A may be replaced with a sacrificial material prior to forming the epitaxial source/drain regions. For example, FIGS. 26-29C illustrate cross-sectional views of forming a stacking transistor according to some other embodiments where the dummy nanostructures 24A are replaced with a sacrificial material prior to forming the lower and upper epitaxial source/drain regions 62L and 62U. In FIGS. 26-29C, like reference numerals indicate like elements formed by like processes as discussed above with respect to FIGS. 2-25 unless otherwise noted. Specifically, FIG. 25 illustrates a structure at a same stage of manufacturing as FIG. 16, above, where source/drain recesses are patterned through the multi-layer stack 22 and the dummy nanostructures 24B are replaced with channel isolation structures 56. The channel isolation structures may be disposed between and separate upper semiconductor nanostructures 26U (collectively) and lower semiconductor nanostructures 26L (collectively).

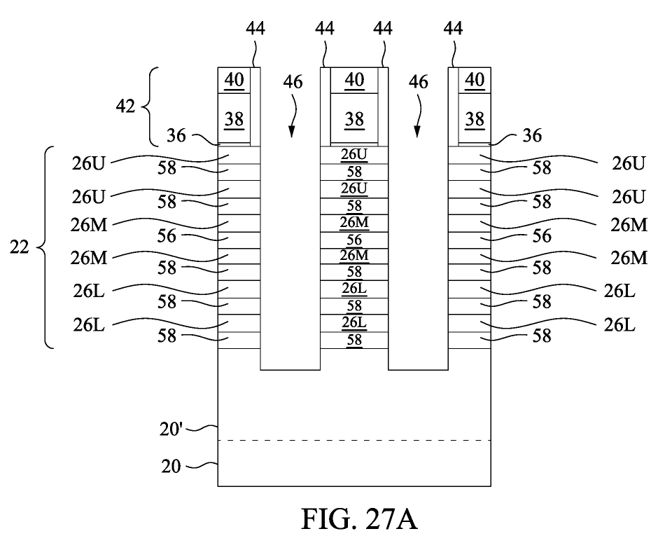

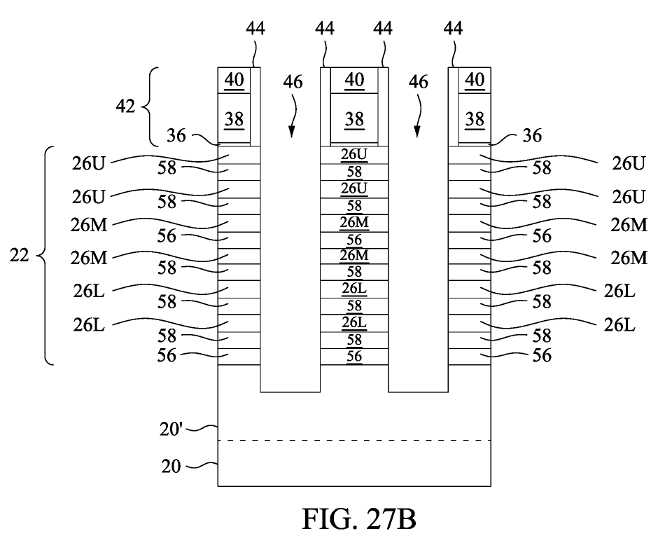

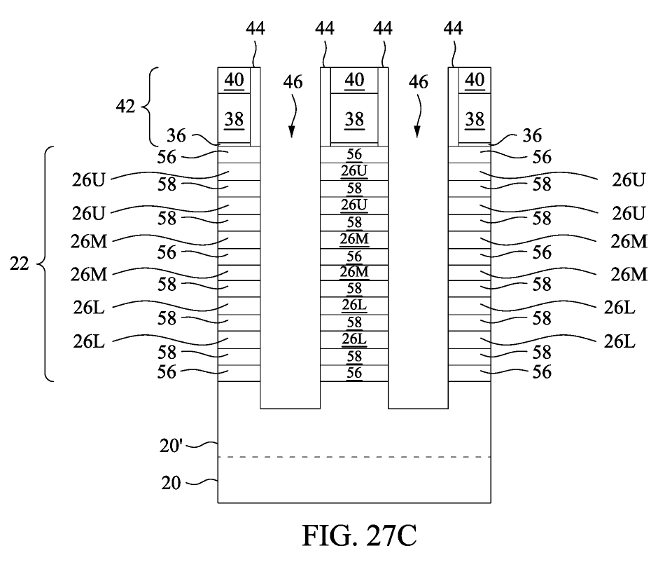

In FIGS. 26-27C, the dummy nanostructures 24A are replaced with a sacrificial material 58 (also referred to as disposable oxide interposers (DOI) 58). Replacing the dummy nanostructures 24A may include etching away the dummy nanostructures 24A using a suitable etch process, such as an isotropic etch process, that is performed through the source/drain recesses 46 as illustrated by FIG. 26. The etch process may be selective to the material of the dummy nanostructures 24A and remove the dummy nanostructures 24A without significantly removing the semiconductor nanostructures 26, the dummy semiconductor nanostructures 26M, or the channel isolation structures 56. In an embodiment in which the dummy nanostructures 24A include, e.g., SiGe, and the semiconductor nanostructures 26/dummy semiconductor nanostructures 26M include, e.g., Si or SiC, a dry etch process with tetramethylammonium hydroxide (TMAH), ammonium hydroxide (NH4OH), or the like may be used to remove the dummy nanostructures 24A.

In FIGS. 27A-27C, the sacrificial material 58 may be formed in the gaps between the semiconductor nanostructures 26. Forming the sacrificial material 58 may include depositing a sacrificial material layer in the source/drain recesses 46 and spaces where the dummy nanostructures 24A were removed. The sacrificial material layer may be deposited by a conformal deposition process, such as CVD, ALD, or the like. The sacrificial material layer may comprise an insulating material such as silicon oxide (e.g., SiO₂), or the like that can be selectively etched from the channel isolation structure 56, the semiconductor nanostructures 26, and the dummy semiconductor nanostructures 26M. The sacrificial material layer may then be etched to form the sacrificial material 58. The etching may be isotropic or anisotropic. For example, the sacrificial material layer may be etched by a wet etch process using diluted HF, or the like as an etchant. In some embodiments, the etching is performed until sidewalls of the sacrificial material 58 is recessed past sidewalls of the semiconductor nanostructures 26. Although sidewalls of sacrificial material 58 are illustrated as being straight in FIGS. 27A-27C, the sidewalls may be concave or convex. Further although sidewalls of the sacrificial material 58 are illustrated as being aligned with sidewalls of the semiconductor nanostructures 26, the sidewalls of the sacrificial material 58 may be recessed from the sidewalls of the semiconductor nanostructures 26 in some embodiments.

FIG. 27A illustrates embodiments consistent with FIGS. 16-18 where the channel isolation structures 56 are only formed between the upper semiconductor nanostructures 26U (collectively) and the lower semiconductor nanostructures 26L (collectively). FIG. 27B illustrates embodiments consistent with FIGS. 19-21 where the channel isolation structures 56 are formed between the upper semiconductor nanostructures 26U (collectively) and the lower semiconductor nanostructures 26L (collectively) as well as between the lower semiconductor nanostructures 26L (collectively) and the semiconductor fin 20’. FIG. 27C illustrates embodiments consistent with FIGS. 22-4 where the channel isolation structures 56 are formed between the upper semiconductor nanostructures 26U (collectively) and the lower semiconductor nanostructures 26L (collectively); between the lower semiconductor nanostructures 26L (collectively) and the semiconductor fin 20’; and over the upper semiconductor nanostructures 26U (collectively).

Replacing the dummy nanostructures 24A with the sacrificial material 58 may provide advantages. For example, in subsequent source/drain formation steps, one or more high temperature processes may be performed to, for example, activate the dopants in the source/drain regions. When the material of the dummy nanostructures 24A (e.g., silicon germanium) is exposed to high temperatures, germanium intermixing and increased roughness at an interfaces between semiconductor nanostructures 26 and the dummy nanostructures 24A may result. Such manufacturing defects may degrade the performance of the resulting transistor devices. For example, when germanium diffuses into the semiconductor nanostructures 26, germanium residue may remain in channel regions of the resulting stacking transistor devices, which negatively affects the performance of the channel regions. By replacing the dummy nanostructures 24A with an insulating material prior to the high temperature processes (e.g., source/drain annealing), manufacturing defects can be reduced and device performance can be improved (e.g., increased current drive, reduced capacitance, and improved short channel effect).

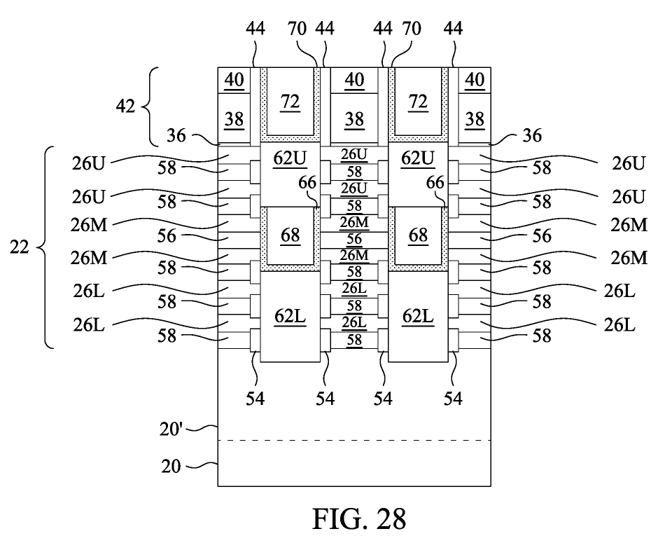

In FIG. 28, inner spacers 54 are formed on sidewalls of the sacrificial material 58. The inner spacers 54 may be formed of a similar material using similar processes as those described above. For example, forming the inner spacers 54 may include recessing the sidewalls of the sacrificial material 58 from sidewalls of the semiconductor nanostructures 26 and the dummy semiconductor nanostructures 26M (if not previously recessed). Then, an insulating material layer is deposited and etched back to form the inner spacers 54. Similar to the above embodiments, the inner spacers 54 and the channel isolation structures 56 may be formed in separate processes to allow for increased flexibility and control in forming different isolation structures in the stacking transistor. The inner spacers 54 may be formed a same material or a different material than the channel isolation structures 56. Further, upper and lower epitaxial source/drain regions 62L and 62U, CESLs 66 and 70, and ILDs 68 and 72 may also be formed in the source/drain recesses 46.

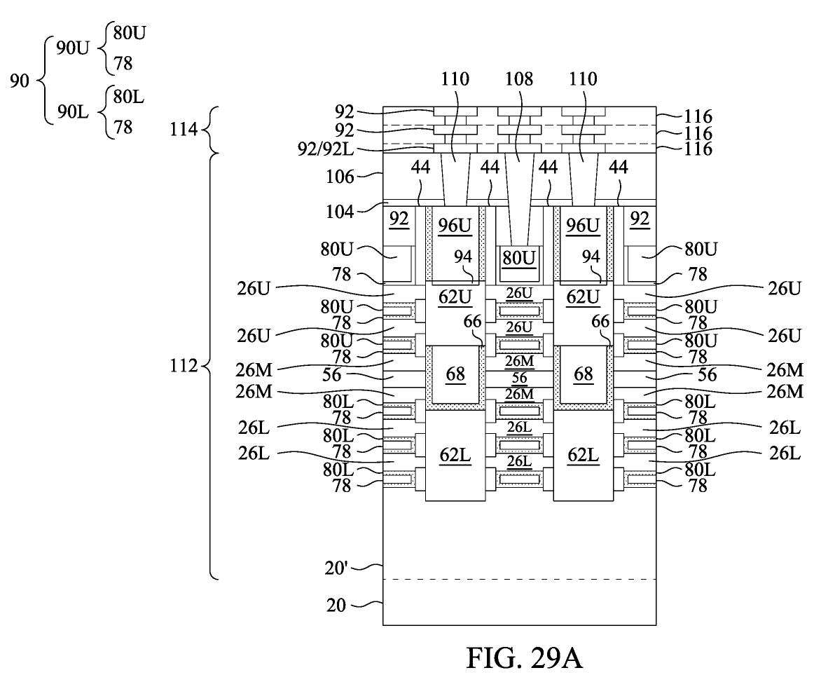

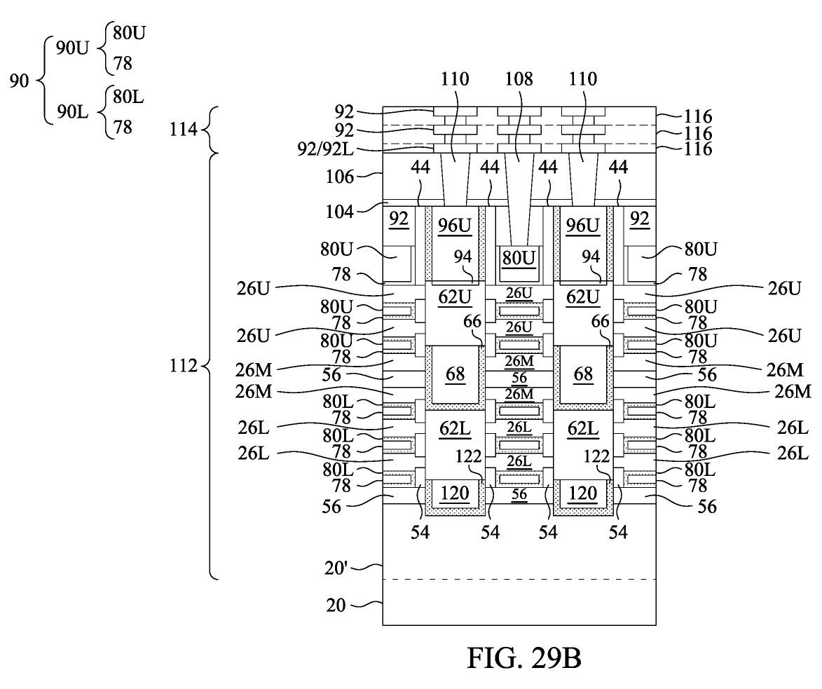

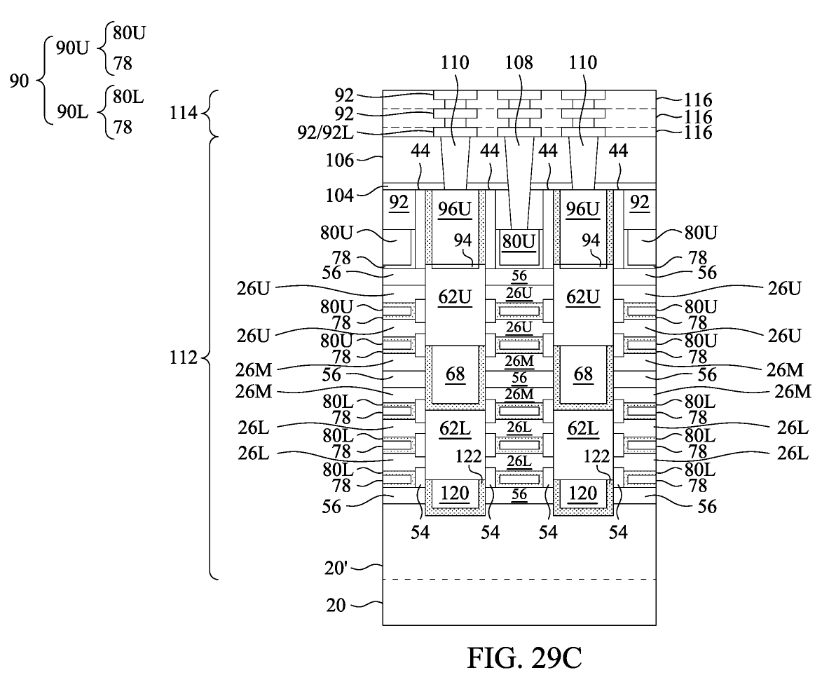

Additional processing steps, including a replacement gate process, gate and source/drain contact formation, and front-side interconnect formation as described above may be performed to arrive at the structures of FIGS. 29A-29C. FIG. 29A illustrates embodiments consistent with FIGS. 16-18 and 27A where the channel isolation structures 56 are only formed between the upper semiconductor nanostructures 26U (collectively) and the lower semiconductor nanostructures 26L (collectively). FIG. 29B illustrates embodiments consistent with FIGS. 19-21 and 27B where the channel isolation structures 56 are formed between the upper semiconductor nanostructures 26U (collectively) and the lower semiconductor nanostructures 26L (collectively) as well as between the lower semiconductor nanostructures 26L (collectively) and the semiconductor fin 20’. FIG. 29C illustrates embodiments consistent with FIGS. 22-24 and 27C where the channel isolation structures 56 are formed between the upper semiconductor nanostructures 26U (collectively) and the lower semiconductor nanostructures 26L (collectively); between the lower semiconductor nanostructures 26L (collectively) and the semiconductor fin 20’; and over the upper semiconductor nanostructures 26U (collectively).

Various embodiments provide a stacking transistor structure including an upper transistor and a lower transistor that are vertically stacked and methods of forming the stacking transistor. Channel isolation structures are formed between and isolate upper channel regions of the upper transistor from lower channel regions of the lower transistor. The channel isolation structures may be formed separately from other isolation structures in the device, such as inner spacers that separate the upper and lower gate stacks from directly contacting upper and lower source/drain regions. Embodiment channel isolation structures provide improved electrical performance (e.g., improved alternating current (AC) flow, improved leakage, or the like) formed by simplified processes flows that are readily implementable.

In some embodiments, a device includes a multi-layer stack comprising: a first plurality of nanostructures; a second plurality of nanostructures over the first plurality of nanostructures; and a first channel isolation structure. The device further includes first source/drain regions on opposing ends of the first plurality of nanostructures; second source/drain regions over the first source/drain regions, the second source/drain regions being on opposing ends of the second plurality of nanostructures; a first gate structure around the first plurality of nanostructures, wherein the first gate structure contacts a first lateral surface of the first channel isolation structure; and a second gate structure around the second plurality of nanostructures. Optionally, in some embodiments, the first channel isolation structure is disposed between the first plurality of nanostructures and the second plurality of nanostructures. Optionally, in some embodiments, the second gate structure contacts a second lateral surface of the first channel isolation structure. Optionally, in some embodiments, the first channel isolation structure is disposed under the first plurality of nanostructures. Optionally, in some embodiments, the device further includes an interlayer dielectric (ILD) under the first source/drain regions, wherein the ILD extends along sidewalls of the first channel isolation structure. Optionally, in some embodiments, the multi-layer stack further comprises a second channel isolation structure over the second plurality of nanostructures. Optionally, in some embodiments, the device further includes first inner spacers between sidewalls of the first gate structure and the first source/drain regions; and second inner spacers between sidewalls of the second gate structure and the second source/drain regions, wherein the first inner spacers and the second inner spacers have a same material composition. Optionally, in some embodiments, the first inner spacers and the second inner spacers have a different material composition than the first channel isolation structure.

In some embodiments, a device includes a first plurality of nanostructures; a second plurality of nanostructures over the first plurality of nanostructures; and a channel isolation structure between the first plurality of nanostructures and the second plurality of nanostructures. The channel isolation structure has a multi-layer structure comprising: a first channel isolation material; and a second channel isolation material between upper and lower portions of the first channel isolation material. The device further includes first source/drain regions on opposing ends of the first plurality of nanostructures; second source/drain regions over the first source/drain regions, the second source/drain regions being on opposing ends of the second plurality of nanostructures; a first gate structure around the first plurality of nanostructures; and a second gate structure around the second plurality of nanostructures. Optionally, in some embodiments, the multi-layer structure further comprises a third channel isolation material on sidewalls of the second channel isolation material, wherein the device further comprises: first inner spacers between sidewalls of the first gate structure and the first source/drain regions; and second inner spacers between sidewalls of the second gate structure and the second source/drain regions, wherein the first inner spacers, the second inner spacers, and the third channel isolation material have a same material composition. Optionally, in some embodiments, the second inner spacers overlap the first channel isolation material, the second channel isolation material, and the third channel isolation material. Optionally, in some embodiments, the second channel isolation material has a lower dielectric constant than the first channel isolation material. Optionally, in some embodiments, the first channel isolation material is harder than the second channel isolation material.

In some embodiments, a methods includes forming a multi-layer stack, the multi-layer stack comprising: lower semiconductor nanostructures that are alternatingly stacked with first dummy nanostructures; upper semiconductor nanostructures that are alternatingly stacked with second dummy nanostructures; and a third dummy nanostructure between the lower semiconductor nanostructures and the upper semiconductor nanostructure. The method further includes patterning a source/drain recess through the multi-layer stack; replacing the third dummy nanostructure with one or more channel isolation materials; after replacing the third dummy nanostructure with the one or more channel isolation materials, recessing sidewalls of the first dummy nanostructures and the second dummy nanostructures; forming inner spacers on recessed sidewalls of the first dummy nanostructures and the second dummy nanostructures; forming a first source/drain region and a second source/drain region in the source/drain recess, the first source/drain region adjoining the lower semiconductor nanostructures, and the second source/drain regions adjoining the upper semiconductor nanostructures; replacing the first dummy nanostructures with a first gate structure; and replacing the second dummy nanostructures with a second gate structure. Optionally, in some embodiments, the third dummy nanostructure is in direct contact with the first dummy nanostructures and the second dummy nanostructures. Optionally, in some embodiments, the third dummy nanostructure is in direct contact with a first dummy semiconductor nanostructure and a second dummy semiconductor nanostructure, wherein the first dummy semiconductor nanostructure and the second dummy semiconductor nanostructure have a same material composition as the lower semiconductor nanostructures and the upper semiconductor nanostructures. Optionally, in some embodiments, replacing the third dummy nanostructure with one or more channel isolation materials comprises: removing the third dummy nanostructure to define a gap between the lower semiconductor nanostructures and the upper semiconductor nanostructures; depositing a first channel isolation material layer on top and bottom surfaces of the gap; filling remaining portions of the gap with a second channel isolation material layer; and removing excess portions of the first channel isolation material layer and the second channel isolation material layer that are disposed outside of the gap to define a first channel isolation material and the a second channel isolation material. Optionally, in some embodiments, the second channel isolation material layer has a lower k-value than the first channel isolation material layer. Optionally, in some embodiments, the method further includes while recessing sidewalls of the first dummy nanostructures and the second dummy nanostructures, recessing a sidewall of the second channel isolation material; and while forming the inner spacers, forming a third channel isolation material on a recessed sidewall of the second channel isolation material. Optionally, in some embodiments, first dummy nanostructures, the second dummy nanostructures, and the third dummy nanostructure each comprise silicon germanium, and wherein the third dummy nanostructure has a higher germanium concentration than the first dummy nanostructures and the second dummy nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a multi-layer stack comprising a first plurality of nanostructures overlapping a first isolation structure;
a first source/drain region interfacing sidewalls of the first plurality of nanostructures in a first cross-sectional view; an interlayer dielectric (ILD) under the first source/drain region, wherein the ILD extends along a sidewall of the first isolation structure in the first cross-sectional view; and
a first gate structure around the first plurality of nanostructures, wherein a bottom surface of the first gate structure interfaces a top surface of the first isolation structure.

2. The device of claim 1, wherein the multi-layer stack further comprises a second plurality of nanostructures, and wherein the device further comprises:
a second source/drain region interfacing sidewalls of the second plurality of nanostructures in the first cross-sectional view; and
a second gate structure around the second plurality of nanostructures.

3. The device of claim 2, wherein the first isolation structure is disposed between the first plurality of nanostructures and the second plurality of nanostructures, and wherein a top surface of the second gate structure interfaces a bottom surface of the first isolation structure.

4. The device of claim 2, wherein the ILD is between the first source/drain region and the second source/drain region.

5. The device of claim 2, wherein the second plurality of nanostructures overlaps the first plurality of nanostructures.

6. The device of claim 5, wherein the multi-layer stack further comprises a second isolation structure between the first plurality of nanostructures and the second plurality of nanostructures.

7. The device of claim 1 further comprising:
first inner spacers between sidewalls of the first gate structure and the first source/drain region, wherein the first inner spacers have a different material composition than the first isolation structure.

8. The device of claim 7, wherein a bottom surface of the first inner spacers interfaces the top surface of the first isolation structure.

9. A method comprising:
forming a channel isolation structure between a first plurality of nanostructures and a second plurality of nanostructures, wherein the channel isolation structure has a multi-layer structure comprising a first isolation material sandwiched between a second isolation material and a third isolation material;
epitaxially growing first source/drain regions on opposing ends of the first plurality of nanostructures; depositing a dielectric layer over the first source/drain regions;
epitaxially growing second source/drain regions over the dielectric layer and on opposing ends of the second plurality of nanostructures; and
forming a first gate structure around the first plurality of nanostructures and a second gate structure around the second plurality of nanostructures.

10. The method of claim 9, wherein forming the channel isolation structure comprises:
removing a dummy nanostructure from between the first plurality of nanostructures and the second plurality of nanostructures to define an opening;
depositing a first material layer on top and bottom surfaces of the opening;
depositing a second material layer on the first material layer; and
patterning the first material layer and the second material layer to provide the first isolation material from the second material layer and the second and third isolation materials from the first material layer.

11. The method of claim 10, wherein forming the channel isolation structure further comprises:
recessing a sidewall of the first isolation material; and
forming a fourth isolation material on a recessed sidewall of the first isolation material.

12. The method of claim 11, wherein the first plurality of nanostructures is alternatingly stacked with first dummy nanostructures, wherein the method further comprises:
recessing sidewalls of the first dummy nanostructures concurrently with recessing sidewalls of the first isolation material; and
forming inner spacers on recessed sidewalls of the first dummy nanostructures concurrently with forming the fourth isolation material, and wherein forming the first gate structure comprises replacing the first dummy nanostructures with the first gate structure.

13. The method of claim 11, wherein the fourth isolation material is sandwiched between the second and third isolation materials.

14. The method of claim 9, wherein the dielectric layer extends along a sidewall of the channel isolation structure.

15. A method comprising:
forming a multi-layer stack, the multi-layer stack comprising:
first semiconductor nanostructures that are alternatingly stacked with first dummy nanostructures; and
a second dummy nanostructure;
patterning a source/drain recess through the multi-layer stack;
replacing the second dummy nanostructure with an isolation structure;
after replacing the second dummy nanostructure with the isolation structure, recessing sidewalls of the first dummy nanostructures;
forming inner spacers on recessed sidewalls of the first dummy nanostructures;
forming a first source/drain region in the source/drain recess, the first source/drain region adjoining the first semiconductor nanostructures; and
replacing the first dummy nanostructures with a first gate structure.

16. The method of claim 15, wherein the second dummy nanostructure interfaces one of the first dummy nanostructures.

17. The method of claim 15, wherein a germanium concentration of the second dummy nanostructure is higher than a germanium concentration of the first dummy nanostructures.

18. The method of claim 15, wherein replacing the second dummy nanostructure comprises:
removing the second dummy nanostructure to define a gap;
depositing a first isolation material layer on top and bottom surfaces of the gap;
filling remaining portions of the gap with a second isolation material layer; and
removing portions of the first isolation material layer and the second isolation material layer that are on sidewalls of the source/drain recess.

19. The method of claim 18, wherein the second isolation material layer has a lower k-value than the first isolation material layer.

20. The method of claim 18 further comprising:
while recessing sidewalls of the first dummy nanostructures, recessing a sidewall of the second isolation material layer; and
while forming the inner spacers, forming a third isolation material on a recessed sidewall of the second isolation material layer.
